(19) United States
(12) Patent Application Publication
(10) Pub. No.: US 2004/0043136 A1
(43) Pub. Date: Mar. 4, 2004

(54) Process of manufacturing organic EL element

(76) Inventor: Kimitaka Ohhata, Tenri-shi (JP)

Correspondence Address: NIXON & VANDERHYE P.C., 1100 North Glebe Road, 8th Floor, Arlington, VA, 22201, US

(21) Appl. No.: 10/229,269

(22) Filed: Aug. 28, 2002

(30) Foreign Application Priority Data
Aug. 28, 2002 (JP) 2001-258036

(51) Int. Cl. B05D 5/12

(52) U.S. Cl. 427/58

(57) ABSTRACT

A method for manufacturing an organic EL element includes the steps of: stacking a heat propagation layer, an exfoliation layer and a transfer layer at least having an organic layer including a light-emitting layer in this order on a base film to form a transfer film; and transferring the transfer layer of the transfer film onto a substrate, thereby forming an organic EL element in which a first electrode, the organic layer and a second electrode are stacked in this order on the substrate, wherein the organic layer to be transferred contains an organic material having a glass-transition temperature of 70° C. or higher.

### CROSS-REFERENCE TO RELATED APPLICATION

This application is related to Japanese Patent Application No. JP2001-258036 filed on Aug. 28, 2001, whose priority is claimed under 35 USC § 119, the disclosure of which is incorporated by reference in its entirety.

### BACKGROUND OF THE INVENTION

1. Field of the Invention

The present invention relates to a process of manufacturing an organic EL element. In particular, it relates to a process of manufacturing an organic EL element utilizing a transfer method.

2. Description of Related Art

An organic EL (electroluminescence) element, in which an organic layer including a light emitting fluorescent layer is sandwiched between electrodes, is self-luminous and shows high visibility. Since an organic material is used as a principal material, the organic EL element has a high degree of flexibility in molecular designing and easily realizes emission of multicolored light. Further, the organic EL element is completely solid and thus has a high impact resistance and ease of handling. Therefore, the organic EL element has currently been applied to surface light sources, display devices and light sources for printers.

In order to apply such an organic EL element to a display device, it is necessary to form light emitting layers of R, G and B separately. Further, in the case of manufacturing a high-resolution display device, a technique of separately providing the light emitting layers of fine patterns is required.

As an example of such a technique, Japanese Unexamined Patent Publication No. Hei 11 (1999)-260549 proposes a process of forming an organic layer by utilizing a transfer method.

According to the above-described transfer method, a transfer layer, i.e., a thin film layer to be transferred such as an organic layer or an electrode, is formed by vapor deposition, spin coating or sputtering on a donor substrate made of a PET (polyethylene terephthalate) film. Then, another substrate is attached to the donor substrate so that the transfer layer contacts the substrate and energy such as laser light or heat is applied from the donor substrate side so that the transfer layer is moved onto the substrate.

However, in the case where the organic layer or the electrode of the organic EL element is formed by the conventional transfer method as described in the above-mentioned publication, in particular where a layer of a fine pattern is transferred, an edge S of the layer may be misaligned with a desired width W of the layer as shown in FIG. 3.

Specifically, in the course of the transfer step, the temperature of the transfer film is raised to 130 to 300° C. and the thermal diffusion inhibits uniform transfer of the organic material.

In the case of irradiating with the laser light, the width of the laser light to be applied is set smaller than the intended width of the transfer layer. However, in this case, the thermal diffusion rate is not uniform so that the transfer layer of the desired width cannot be obtained.

### SUMMARY OF THE INVENTION

In view of the above-described problems, the present invention has been achieved to provide a process of manufacturing an organic EL element capable of forming layers of fine patterns separately by utilizing a transfer method.

According to the present invention, provided is a process of manufacturing an organic EL element comprising the steps of: stacking a heat propagation layer, an exfoliation layer and a transfer layer at least having an organic layer including a light-emitting layer in this order on a base film to form a transfer film; and transferring the transfer layer of the transfer film onto a substrate, thereby forming an organic EL element in which a first electrode, the organic layer and a second electrode are stacked in this order on the substrate, wherein the organic layer to be transferred contains an organic material having a glass-transition temperature of 70° C. or higher.

That is, the inventors of the present invention have researched thermal characteristics and transfer characteristics of the organic material to be contact with the substrate and found the process of manufacturing the organic EL element which allows transferring a layer of a desired width if the glass-transition temperature of the organic material is 70° C. or higher.

These and other objects of the present application will become more readily apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

FIG. 1 is a sectional view illustrating an example of a structure of an organic EL element according to an embodiment of the present invention;

FIG. 2 is a front sectional view illustrating a structure of a transfer film according to an embodiment of the present invention; and

FIG. 3 is a plan view illustrating a relationship between an edge S of a transfer layer formed by a conventional transfer method and a desired width W of the transfer layer.

### DESCRIPTION OF THE PREFERRED EMBODIMENTS

A structure of the organic EL element according to the present invention and an embodiment of the manufacturing process thereof are described hereinafter with reference to the figures. However, the present invention is not limited thereto.

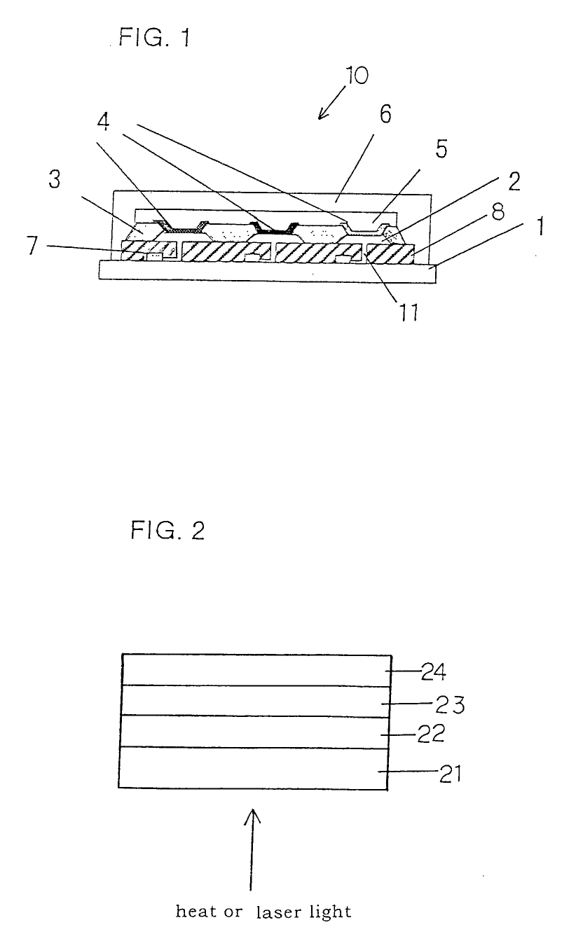

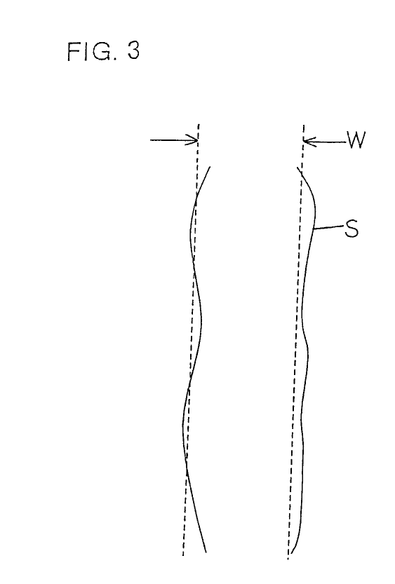

FIG. 1 is a sectional view illustrating a structure of the organic EL element according to an embodiment of the present invention.

FIG. 1 shows an organic EL element 10. On a substrate 1, formed in the following order are a switching element 7, a flattening layer (insulating film) 8, a first electrode 2, a barrier 3, an organic layer 4 including a light emitting layer, a second electrode 5 and a sealing member 6. A through hole 11 penetrating the flattening layer 8 is formed to connect the first electrode 2 and the switching element 7. The switching element 7 and the second electrode 5 are connected to a power source circuit which is not shown. In the organic EL element 10, the light emitting layer is driven to emit light in accordance with a signal from the switching element 7 and the emitted light is taken out of the side where the substrate 1 is formed or the opposite side, i.e., the side where the second electrode 5 is formed.

The substrate 1 is arranged at least one side of the first and second electrodes 2 and 5. An insulative substrate which is translucent or non-translucent can be used as the substrate 1.

Material for the substrate 1 is not particularly limited as long as it is generally used in a conventional organic EL element. For example, inorganic materials such as quartz, soda glass and ceramic or organic materials such as polyimide and polyester may be used.

It is desired that light emitted from the light emitting layer is taken out of the second electrode 5 disposed on the opposite side of the substrate 1 as observed from the light emitting layer in order to improve the open area ratio. In this case, it is preferred that the substrate 1 has a high light absorption coefficient in the visible range to improve contrast.

The transfer can accurately be performed to a desired position by providing on the substrate 1 a maker for alignment of the transfer film in the course of the transfer.

As required, the switching element 7 such as a TFT element or an MIM element or a capacitor for storing data may be incorporated in the substrate 1. Therefore, it is preferred that the substrate 1 is made of a material which is highly resistant against heat and chemicals so that the above-mentioned components such as the switching element 7 can be formed.

Materials for the first and second electrodes 2 and 5 are not particularly limited, but it is preferred that one of them is made of transparent metal. Examples thereof include inorganic materials such as thin films of indium-tin oxide (ITO), SnO₂ and Au and organic materials such as thin films of polyaniline and polythiophene.

Material for the other electrode is not particularly limited. For example, magnesium, lithium, calcium, silver, aluminum, indium, cesium, copper and the like may be used. These metals may be used in the form of a simple substance, an alloy or a layered structure with different materials.

The barrier 3 functions as a blocking film for preventing leakage between the electrodes, crosstalk between pixels and mixing of the organic materials between pixels. The barrier 3 is preferably provided around the pixels or in part of the pixels.

Material for the barrier 3 is not particularly limited, but inorganic materials such as SiO₂ and SiN, organic materials such as polyimide and photoresist or a combination thereof may be used.

The size and shape of the barrier 3 are not particularly limited, but a thickness thereof is preferably 5 μm or less. If the thickness of the barrier is 5 μm or more, a gap is generated around the barrier 3 when the transfer film is adhered to a substrate provided with the barrier 3 as mentioned later, which may cause failure in the transfer.

The organic layer 4 may have a layered structure including charge transport layers such as a hole transport layer, a hole injection layer, an electron transport layer and an electron injection layer, in addition to the light emitting layer.

The organic layer 4 may be single-layered or multilayered and the structure between the electrodes is not particularly limited. Specifically, the organic layer 4 may have a structure of a first electrode/a light emitting layer/a second electrode, a first electrode/a hole transport layer/a light emitting electron transport layer/a second electrode, or a first electrode/a hole transport layer/a light emitting layer/an electron transport layer/a second electrode.

The organic layer 4 may also include inorganic materials such as an electron injection material, a charge control material and the like without particular limitation.

The light emitting layer may be made of a light emitting low molecular weight material or a light emitting polymeric material which have been utilized in the organic EL element.

Examples of the light emitting low molecular weight material include 8-hydroxyquinoline derivatives, thiazole derivatives, benzoxazole derivatives, quinacridone derivatives, styryl arylene derivatives, perylene derivatives, oxazole derivatives, oxadiazole derivatives, triazole derivatives, triphenylamine derivatives, fluorescent metal complexes and the like. However, these are not limitative.

Examples of the light emitting polymeric material include polyparaphenylene vinylene (PPV) derivatives, polyvinyl carbazole (PVC), polyfluorene derivatives and polythiophene derivatives. However, these are not limitative. These materials may be combined, or additives (e.g., metals such as lithium and cesium, metal oxides and metal fluorides) such as dopants (e.g., coumarin derivatives, quinacridone derivatives and known dyes for laser, which are not limitative) may be used together.

Examples of material for the hole transport layer include conductive polymeric materials such as NPD (4,4′-bis[N-naphthyl-N-phenyl-amino]biphenyl), triphenylamine derivatives, PPV derivatives, PVC, polyaniline and PEDOT/PSS, P-type semiconductor materials and the like, but not limited thereto.

Examples of material for the hole injection layer include CuPc (copper phthalocyanine) and triphenylamine derivatives, but not limited thereto.

Examples of material for the electron transport layer include oxadiazole derivatives, organic metal complexes, PPV derivatives and Alq₃ (aluminum quinoline), but not limited thereto.

Examples of material for the electron injection layer include LiF (lithium fluoride), Li₂O (lithium oxide) and CsF (cesium fluoride), but not limited thereto.

According to the present invention, the organic layer 4 contains an organic material having a glass-transition temperature Tg of 70 to 300° C.

Examples of such an organic material include NPD (4,4′-bis[N-naphthyl-N-phenyl-amino]biphenyl; Tg=95° C.), Alq₃ (aluminum quinoline; Tg=175° C.), m-MTDATA (4,4′,4″-tris[3-methylphenylamino]triphenylamine; Tg=75° C.) or a material prepared by mixing at least one of these materials and at least one polymeric material (the glass-transition temperature Tg may not be within the range of 70 to 300° C.).

These organic materials may entirely or partially comprise the organic layer 4. It is preferred that the above-mentioned organic materials having a glass-transition temperature Tg of 70 to 300° C. is formed on the surface of the transfer layer 24, i.e., the surface which will contact the surface of the substrate 1 at the transfer.

If the glass-transition temperature Tg of the organic material is 70° C. or lower, undesirable transfer may occur by diffusion of heat generated during the transfer. This makes the transfer of the layer of a desired shape or width difficult, which leads to deterioration of display quality and leakage.

On the other hand, the glass-transition temperature Tg of 300° C. or higher is not preferable because problems may possibly occur in the organic layer 4 or the switching element 7.

The sealing member 6 functions to prevent moisture and oxygen from contacting the organic layer 4.

Structure and material for the sealing member 6 are not particularly limited. Specifically, the sealing may be achieved by bonding a known sealing cap, passivation with an organic or inorganic material or lamination.

It is preferred that the sealing member 6 is highly transparent in the case where light emitted from the light emitting layer is taken out of the sealing member 6 side. As required, the sealing member 6 may be formed to have the function as a polarizing plate or combined with a vapor barrier.

FIG. 2 shows a front sectional view illustrating a structure of the transfer film according to an embodiment of the present invention.

As shown in FIG. 2, the transfer film is comprised of a multilayered structure at least including a base film 21, a heat propagation layer 22, an exfoliation layer 23 and a transfer layer 24. At the transfer, light or heat is applied from the base film 21 side toward the substrate 1 (in the direction of an arrow shown in FIG. 2).

The base film 21 is preferably made of a material which is transparent and physically flexible. If the base film 21 is highly flexible, the transfer film can be disposed on the substrate 1 without generating a gap between the substrate 1 even if the surface of the substrate 1 is uneven, i.e., on which the first electrode 2 and the barrier 3 have been formed.

Material for the base film 21 is not particularly limited as long as it has the above-mentioned characteristics. For example, known polymeric materials such as PET and PMMA may be used.

The base film 21 preferably has a thickness of 0.01 to 1000 μm in view of the flexibility thereof.

The heat propagation layer 22 functions to propagate heat so that the transfer is carried out with efficiency, and may be made of a polymeric material such as poly a-methylstyrene, for example.

The heat propagation layer 22 preferably has a layered structure of a light-heat conversion layer and a heat propagation layer. In the case where the transfer is carried out by making use of an exothermic reaction, the heat propagation layer 22 preferably has a layered structure of an exothermic layer and a heat propagation layer.

If the transfer is performed by using a laser, the light-heat conversion layer is made of a material capable of effectively converting laser light to heat. Examples of such a material include a metal film comprised of aluminum, aluminum oxide and/or aluminum sulfide, an organic film made of a polymeric material (e.g., a thermosetting epoxy resin) in which carbon black, graphite or infrared dye is dispersed and the like. However, they are not limitative.

The heat propagation layer 22 may be comprised of a black-colored layer in which carbon black or the like is dispersed in these materials.

The exfoliation layer 23 may be made of any material as long as it is known in the art, for example, poly a-methylstyrene and a thermo-foaming resin may be used.

On the thus formed transfer film, i.e., on the surface of the exfoliation layer 23, a transfer layer 24 is formed. The transfer layer 4 is comprised of an organic layer 4 or the organic layer 4 and a second electrode 5 to be transferred to the substrate 1.

The organic layer 4 formed as the transfer film 24 may be single-layered or multilayered and its structure is not particularly limited.

A method of forming the organic layer 4 on the transfer film is not particularly limited and known techniques may be used, for example, vacuum deposition, sputtering, spin coating, ink jet method, printing or a combination thereof.

In the case where the light emitted from the light emitting layer is taken out of the second electrode 5 side, the second electrode 5 needs to be transparent to improve efficiency in taking the light out. At this time, if the transparent second electrode 5 serves as a positive electrode, it is preferred that a portion of the organic layer 4 contacting the substrate 1 functions as an electron transport layer and a portion of the organic layer 4 contacting the second electrode 5 functions as a hole injection layer. In this case, the electron transport layer is preferably made of aluminum quinoline (Alq₃) which is thermally stable and effectively transports the electrons.

Explanation is given of the steps of transferring the transfer layer 24 to the substrate 1.

The transfer layer 24 is transferred to the substrate 1 by attaching the transfer film to the substrate 1 and applying laser light thereon. The switching element 7 and the first electrode 2 may be formed on the substrate 1.

It is preferred that the substrate 1 and the transfer film are attached such that air bubbles do not remain between them. If the air bubbles remain, a desired pattern and thickness may not be obtained after the transfer.

A method of deaeration for preventing the air bubbles from remaining between the substrate 1 and the transfer film is not particularly limited. For example, a vacuum pump may be used between the substrate 1 and the transfer firm or a roller may be used over the transfer film disposed on the substrate 1, or these methods may be combined.

Next, laser light is applied to carry out the transfer.

At this time, the laser light is applied to a portion to be transferred. That is, only a portion irradiated with the laser light is transferred. An output of the laser light is not particularly limited. However, if the output is too high, the organic material may be damaged. Further, if the output is too low, the transfer may not be carried out sufficiently to form a patchy layer.

The kind and wavelength of the laser to be used are not particularly limited. For example, a YAG laser and a semiconductor laser are preferable because their outputs are stable.

After the portion to be transferred is irradiated with the laser light, the transfer film is exfoliated. Thereby, the transfer is completed.

In addition to the above-mentioned method in which the laser light is irradiated and converted to heat, there is another transfer method in which the portion to be transferred is directly heated, e.g., by pressing a heated metal mask thereon.

Hereinafter, examples of the process of manufacturing the organic EL element according to the present invention will be described.

### EXAMPLE 1

A transfer film was manufactured by a known technique. First, an epoxy resin layer dispersed with carbon was formed in a thickness of 5 nm as a light-heat conversion layer on a PET base film 21 of 0.1 mm thick. Then, a poly α-methylstyrene film of 1 nm thick was formed thereon as an exfoliation layer 23 and an NPD layer (Tg=95° C.) of 10 nm thick was formed as a transfer layer 24 on the exfoliation layer 23 by vacuum deposition. Thus, a transfer film was obtained, in which the transfer layer 24 containing an organic material for forming an organic layer 4 on a substrate 1 was formed on its outermost side.

The thus obtained transfer film was attached to a substrate 1 on which a first electrode 2 made of ITO had been formed and a roller was used over the transfer film for deaeration. Then, laser light having an irradiation width of 50 nm was irradiated at an energy amount of 16 w to carry out the transfer.

Table 1 shows the results.

TABLE 1

| | Transfer characteristic | Tg (° C.) |
|---|---|---|
| Example 1 | ◯ | 95 |
| Example 2 | ◯ | 175 |
| Example 3 | ◯ | 95 |
| Example 4 | ◯ | 175 |
| Example 5 | ◯ | 175 |
| Example 6 | ◯ | 175 |
| Example 7 | ◯ | 175 |
| Example 8 | ◯ | 75 |
| Comparative | X | 63 |
| Example 1 | | |

In Table 1, “◯” in the transfer characteristic column signifies that the offset rate of the obtained transfer layer with respect to a desired width of the transfer layer was within the range of ±7%, whereas “X” means that the offset rate was out of the range.

### EXAMPLE 2

A transfer film was formed in the same manner as in Example 1 except that Alq₃ (Tg=175° C.) was used as the organic material. The results are shown in Table 1.

### EXAMPLE 3

A transfer film was formed in the same manner as in Example 1 except that an Alq₃ layer of 50 nm thick and an NPD layer of 50 nm thick were stacked in this order by vacuum deposition to function as the transfer layer 24 for forming the organic layer 4. The results are shown in Table 1.

### EXAMPLE 4

A transfer film was formed in the same manner as in Example 1 except that an NPD layer of 50 nm thick and an Alq₃ layer of 50 nm thick were stacked in this order by vacuum deposition to function as the transfer layer 24 for forming the organic layer 4. The results are shown in Table 1.

### Example 5

A transfer film was formed in the same manner as in Example 1 except that a TPD layer (Tg=63° C.) of 50 nm thick and an Alq₃ layer of 50 nm thick were stacked in this order by vacuum deposition to function as the transfer film 24 for forming the organic layer 4. The results are shown in Table 1.

### Example 6

This example refers to a structure in which an organic material having a glass-transition temperature of 70° C. or higher is provided on the surface of the transfer layer 24 and an organic material having a glass-transition temperature of 70° C. or lower was disposed on the surface of the substrate to be contact with the transfer layer 24.

First, an Alq₃ layer of 50 nm thick was formed by vacuum deposition. A TPD layer (Tg=63° C.) of 50 nm thick was formed on the substrate 1 provided with ITO. Then, the transfer film on which the Alq₃ layer had been formed was attached to the substrate 1 on which the TPD layer had been formed and laser light was applied for transfer. The results are shown in Table 1.

### EXAMPLE 7

This example refers to a structure in which the transfer layer 24 is the organic layer 4 to be transferred onto the substrate 1 on which a switching element 7 and a first electrode 2 had been formed.

A transfer film was formed in the same manner as in Example 1. First, a CuPc layer of 20 nm thick was formed by vacuum deposition as a hole injection layer. Then, an NPD film of 40 nm thick and an Alq₃ layer of 60 nm thick were formed in this order as a hole transport layer and a light emitting electron transport layer, respectively. These three layers function as the transfer layer 24, in which the Alq₃ layer is the organic layer 4 to contact the substrate 1.

On the other hand, the substrate 1 on which a TFT element and a first electrode 2 had been formed was subjected to UV ozone washing. Then, the transfer film was attached thereto and a roller was applied over the transfer film for deaeration. Thereafter, laser light was applied from the transfer film side at an energy amount of 16 w. After the transfer layer 24 was transferred through the laser light irradiation, the transfer film was exfoliated to complete the organic layer 4.

The above-mentioned transfer step using the laser was carried out in a dry nitrogen atmosphere. Subsequently, the substrate 1 provided with the organic layer 4 was placed in a vacuum deposition apparatus to form an ITO layer of 100 nm thick by sputtering as a first electrode 2. Then, a transparent glass was adhered thereto as a sealing member 6, thereby completing an organic EL display in which light emitted from the light emitting layer is taken out of the second electrode 5 side.

To the thus manufactured organic EL display, a driving power source was connected and a signal was input, thereby completing a full-color display device capable of displaying moving images.

In Example 7, the light emitted from the light emitting layer was taken out of the second electrode 5 side. Therefore, the obtained display had a high open area ratio.

### EXAMPLE 8

A transfer film was formed in the same manner as in Example 1 except that m-MTDATA (4,4′,4″-tris [3-methylphenylamino]triphenylamine; Tg=75° C.) was used as the organic material. The results are shown in Table 1.

In this example, the organic layer 4 having a desired width was obtained because the glass-transition temperature of the organic material was higher than 70° C.

### COMPARATIVE EXAMPLE 1

A transfer film was formed in the same manner as in Example 1 except that TPD (Tg=63° C.) was used as the organic material. The results are shown in Table 1.

In this example, the organic layer 4 having a desired width could not be obtained because the glass-transition temperature of the organic material was lower than 70° C.

The results shown in Table 1 indicate that the organic layer 4 having a desired width can be obtained if the glass-transition temperature of the organic material provided on the surface of the transfer film is 70° C. or higher. From the results, the present invention provides a process of manufacturing an organic EL element capable of forming layers of fine patterns separately.

What is claimed is:

1. A method for manufacturing an organic EL element comprising the steps of:
stacking a heat propagation layer, an exfoliation layer and a transfer layer at least having an organic layer including a light-emitting layer in this order on a base film to form a transfer film; and transferring the transfer layer of the transfer film onto a substrate, thereby forming an organic EL element in which a first electrode, the organic layer and a second electrode are stacked in this order on the substrate,
wherein the organic layer to be transferred contains an organic material having a glass-transition temperature of 70° C. or higher.

2. A method as claimed in claim 1, wherein the organic material is formed on a surfice of the transfer layer.

3. A method as claimed in claim 1, wherein the substrate has a switching element and the first electrode, and the transfer layer is composed of an organic layer, or the organic layer and the second electrode.

4. A method as claimed in claim 3, wherein the light emitted from the light emitting layer is taken out of a second electrode side.

5. A method as claimed in claim 3, wherein the switching element is a TFT element.

6. A method as claimed in claim 1, wherein heat or laser light is applied when the transfer layer is transferred to the substrate.

7. A method as claimed in claim 1, wherein the organic material is made of an electron transport material.

8. A method as claimed in claim 7, wherein the electron transport layer is made of aluminum quinoline.

9. A method as claimed in claim 1, further comprising the step of providing a marker on the substrate for positioning the transfer film at a desired position on the substrate.

10. A method as claimed in claim 1, wherein the heat propagation layer has a layered structure of a light-heat conversion layer and a heat propagation layer or has a layered structure of an exothermic layer and a heat propagation layer.
